(19) United States
(12) Patent Application Publication
(10) Pub. No.: US 2026/0205086 A1
(43) Pub. Date: Jul. 16, 2026

(54) Oscillator Manufacturing Method

(71) Applicant: SEIKO EPSON CORPORATION, Tokyo (JP)

(72) Inventor: Koichi MIZUGAKI, Suwa (JP)

(21) Appl. No.: 19/401,985

(22) Filed: Nov. 26, 2025

(30) Foreign Application Priority Data
Nov. 28, 2024 (JP) 2024-207074

(51) Int. Cl. H03H 3/013; G01R 31/28

(52) U.S. Cl. CPC H03H 3/013; G01R 31/2824

(57) ABSTRACT

An oscillator manufacturing method includes: preparing a wafer substrate including a mother substrate on which a control circuit and an external terminal are disposed, a vibration element, and a lid that accommodates the vibration element together with the mother substrate; a first measurement step of supplying a first signal to the control circuit via the external terminal to measure a frequency of the oscillator; a step of storing temperature compensation data as correction information to be used in a correction circuit in a storage section and adjusting the frequency of the oscillator to a first frequency; individualizing the wafer substrate for each oscillator including the vibration element, the control circuit, and the external terminal; a second measurement step of measuring the frequency of the oscillator; and performing a fault diagnosis on the oscillator by comparing the frequency of the oscillator measured in the second measurement step with the first frequency.

The present application is based on, and claims priority from JP Application Serial Number 2024-207074, filed Nov. 28, 2024, the disclosure of which is hereby incorporated by reference herein in its entirety.

### BACKGROUND

### 1. Technical Field

The present disclosure relates to an oscillator manufacturing method.

### 2. Related Art

JP-A-2008-35486 discloses a manufacturing method of a temperature compensated oscillator (TCXO) that measures a frequency temperature characteristic in a wafer state, writes temperature compensation data into a storage element provided in an IC element, and then performs individuation.

Meanwhile, there is a concern that an oscillation frequency may shift after the individuation. In addition, in the technique disclosed in JP-A-2008-35486, there is also a problem that a measurement terminal is separated during the individuation, and thus the oscillation frequency cannot be measured after the individuation.

### SUMMARY

According to an aspect of the present disclosure, there is provided an oscillator manufacturing method including: preparing a structure including a control circuit having a storage section and a correction circuit, a mother substrate on which a terminal coupled to the control circuit is disposed, a vibration element that is disposed corresponding to the control circuit and constitutes an oscillator together with the control circuit, and a lid that accommodates the vibration element together with the mother substrate; a first measurement step of supplying a signal to the control circuit via the terminal to measure a frequency of the oscillator; storing, in the storage section, correction information to be used in the correction circuit in accordance with the measured frequency, and adjusting the frequency of the oscillator to a first frequency; individualizing the structure for each oscillator including the vibration element, the control circuit, and the terminal; a second measurement step of supplying the signal to the control circuit via the terminal to measure the frequency of the oscillator; and performing a fault diagnosis on the oscillator by comparing the frequency of the oscillator measured in the second measurement step with the first frequency.

### BRIEF DESCRIPTION OF THE DRAWINGS

FIG. 1 is a configuration diagram illustrating a schematic configuration of an apparatus group used in an oscillator manufacturing method according to Embodiment 1.

FIG. 2A is an enlarged perspective view of an oscillator provided on a wafer substrate as viewed from a Lid substrate side.

FIG. 2B is an enlarged perspective view of the oscillator provided on the wafer substrate as viewed from a mother substrate side.

FIG. 3 is a cross-sectional view taken along a line III-III in FIG. 2A.

FIG. 4 is a functional configuration diagram of the oscillator.

FIG. 5 is a flowchart illustrating an oscillator manufacturing method.

FIG. 6 is a flowchart illustrating details of a base substrate preparing step.

FIG. 7 is a flowchart illustrating details of a first measurement step.

FIG. 8 is a flowchart illustrating details of an adjustment step.

FIG. 9 is a flowchart illustrating details of a second measurement step.

FIG. 10 is a timing chart illustrating examples of an input signal and an output signal of a measurement section.

FIG. 11 is a diagram illustrating a measurement condition.

FIG. 12 is a graph illustrating a temperature characteristic of a frequency of the oscillator.

### DESCRIPTION OF EMBODIMENTS

In embodiments of the present disclosure, components illustrated in each drawing may be illustrated with different scales of dimensions in order to make the components easy to see. The drawing may illustrate three axes, an X-axis, a Y-axis, and a Z-axis, which are orthogonal to each other.

In the following description, tip sides of arrows of the three axes may be described as “plus side”s, and base sides of the arrows may be described as “minus side”s. A direction parallel to the X-axis may be described as an “X-axis direction”, a direction parallel to the Y-axis may be described as a “Y-axis direction”, and a direction parallel to the Z-axis may be described as a “Z-axis direction”.

Hereinafter, “plan view” means that an object is viewed from the plus side of the Z-axis direction of the object or from the minus side of the Z-axis direction. The plus side in the Z-axis direction may be described as “upward”, and the minus side in the Z-axis direction may be described as “downward”.

Description of an upper surface of a certain configuration is assumed to indicate a surface on the plus side in the Z-axis direction of the configuration, for example, “an upper surface of a substrate” indicates a surface on the plus side in the Z-axis direction of the substrate. Description of a lower surface of the certain configuration is assumed to indicate a surface on the minus side in the Z-axis direction of the configuration, for example, “a lower surface of the substrate” indicates a surface on the minus side in the Z-axis direction of the substrate.

### 1. Embodiment 1

In this section, a manufacturing method of an oscillator 1 according to Embodiment 1 will be described in the following order.
1.1. Outline Configuration of Apparatus Group Used in Oscillator Manufacturing Method
1.2. Configuration of Oscillator
1.3. Oscillator Manufacturing Method

### 1.1. Outline Configuration of Apparatus Group Used in Oscillator Manufacturing Method

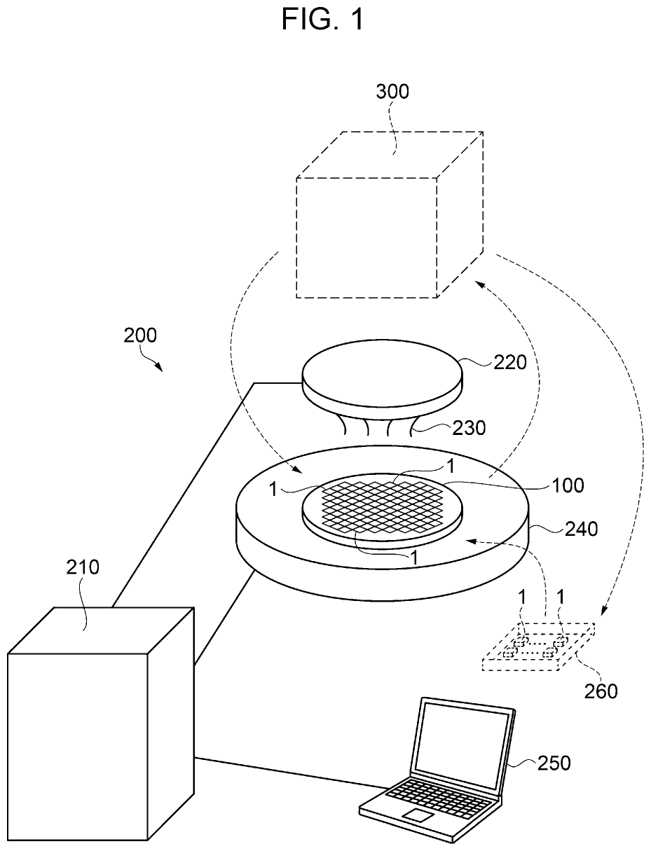

FIG. 1 is a configuration diagram illustrating a schematic configuration of an apparatus group used in a manufacturing method of the oscillator 1 according to Embodiment 1.

As illustrated in FIG. 1, the apparatus group used in the manufacturing method of the oscillator 1 according to Embodiment 1 includes an inspection apparatus 200 and a manufacturing apparatus 300. The inspection apparatus 200 includes a measurement device 210, a probe card 220, a probe 230, a prober 240, a computer 250, a tray 260, and a temperature adjustment device and a temperature sensor (not illustrated), and measures a frequency of the oscillator 1, adjusts the frequency of the oscillator 1, and perform a fault diagnosis on the oscillator 1 in a state in which the oscillator 1 is in a state of a wafer substrate 100 or in a state of being individualized. The manufacturing apparatus 300 includes a film forming device, an etching device, a substrate bonding device, a scribing device, and the like, and manufactures and individualizes the wafer substrate 100 in which a plurality of oscillators 1 are formed. In the present embodiment, the wafer substrate 100 is an example of a structure.

### 1.2. Configuration of Oscillator

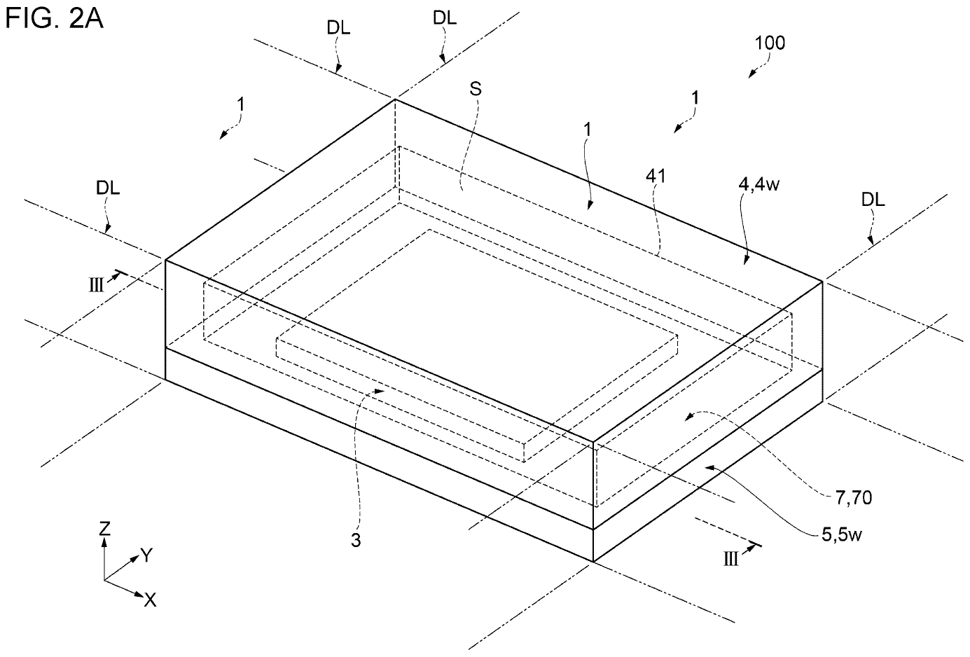

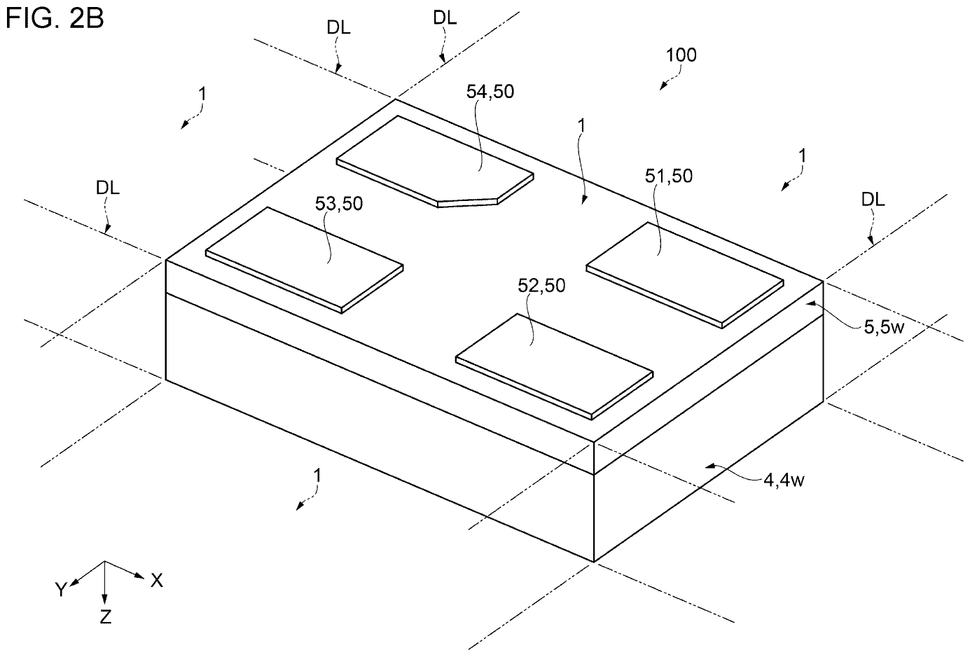

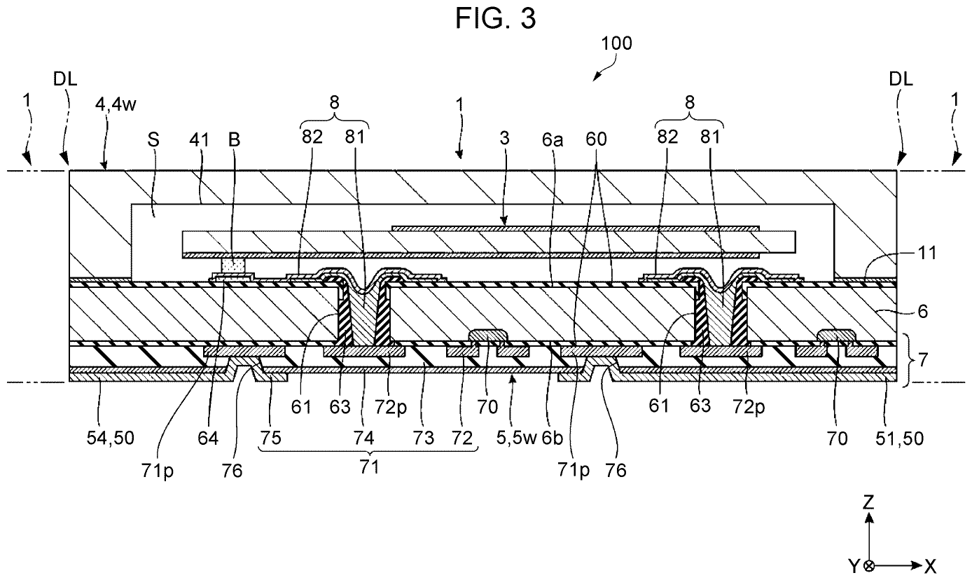

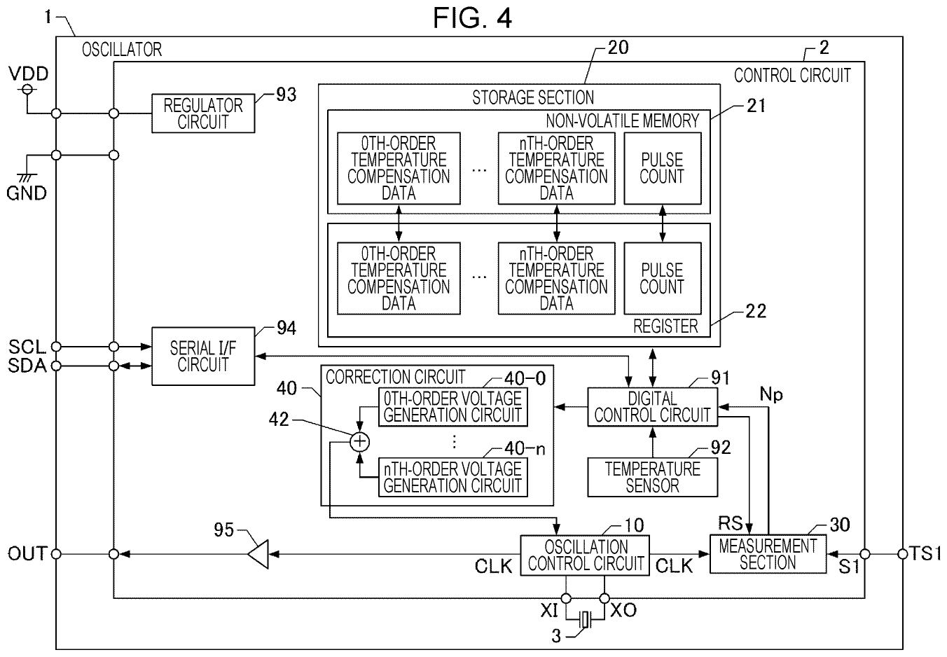

FIG. 2A is an enlarged perspective view of the oscillator 1 provided on the wafer substrate 100 as viewed from a side of a lid 4, and FIG. 2B is an enlarged perspective view of the oscillator 1 provided on the wafer substrate 100 as viewed from a side of a mother substrate 5. FIG. 3 is a cross-sectional view taken along a line III-III in FIG. 2A. FIG. 4 is a functional configuration diagram of the oscillator 1.

The wafer substrate 100 includes a base substrate 5w, a Lid substrate 4w bonded to the base substrate 5w, and a vibration element 3 disposed between the base substrate 5w and the Lid substrate 4w. In the present embodiment, both the base substrate 5w and the Lid substrate 4w are formed by processing a silicon wafer.

The plurality of oscillators 1 corresponding to the number of vibration elements 3 are formed at the wafer substrate 100. The wafer substrate 100 is individualized into each oscillator 1 by being cut at a position of a division line DL.

The oscillator 1 includes the mother substrate 5, the vibration element 3 disposed on an upper surface of the mother substrate 5, and the lid 4 that covers the vibration element 3 and is bonded to the upper surface of the mother substrate 5. In the oscillator 1, a package for accommodating the vibration element 3 is formed by the mother substrate 5 and the lid 4, and the vibration element 3 is accommodated in an accommodation space S.

### 1.2.1. Configuration of Mother Substrate 5

As illustrated in FIG. 2B, an external terminal 50 is provided on a lower surface of the mother substrate 5. In the present embodiment, the external terminal 50 includes four external terminals 51, 52, 53, and 54. As illustrated in FIG. 3, the external terminal 50 is electrically coupled to an electrode pad 71p of a wiring layer 72 via a contact hole 76.

The mother substrate 5 includes a silicon substrate 6, a semiconductor circuit 7 provided on a lower surface 6b side of the silicon substrate 6, and the external terminal 50 provided on a lower surface side of the semiconductor circuit 7, and the external terminal 50 and the semiconductor circuit 7 are electrically coupled to each other via the electrode pad 71p. The external terminal 50 also serves as a terminal for measurement in a step by the inspection apparatus 200 (see FIG. 1).

The silicon substrate 6 is obtained by performing individuation on the base substrate 5w made of a silicon wafer. The silicon substrate 6 may be formed of, for example, a wafer made of a semiconductor material other than silicon such as Ge, GaP, GaAs, and InP.

The silicon substrate 6 has a through-hole 61 penetrating an upper surface 6a and a lower surface 6b. The through-hole 61 can be formed by, for example, reactive ion etching (RIE). Therefore, the through-hole 61 having a high aspect ratio can be formed.

An insulating film 60 is formed at the upper surface 6a and the lower surface 6b of the silicon substrate 6. The insulating film 60 is made of, for example, silicon oxide (SiO₂). In addition, the insulating film 60 can be formed by, for example, sputtering.

The semiconductor circuit 7 includes a control circuit 2 having a storage section 20, a correction circuit 40, and the like, which will be described below. The semiconductor circuit 7 includes a plurality of elements 70 formed at the lower surface 6b of the silicon substrate 6 and a laminate 71 laminated on the lower surface 6b of the silicon substrate 6.

The laminate 71 includes the wiring layer 72 formed at the lower surface 6b of the silicon substrate 6, an insulating layer 73 formed at a lower surface of the wiring layer 72, a passivation film 74 formed at a lower surface of the insulating layer 73, and a terminal layer 75 formed at a lower surface of the passivation film 74.

The wiring layer 72 electrically couples the plurality of elements 70 to each other via a wiring, a contact hole, or a through-electrode included in the wiring layer 72 to constitute the semiconductor circuit 7. The element 70 is, for example, a transistor, a resistor, a capacitive element, or the like. The wiring layer 72 may have a plurality of layers.

In this manner, by forming the semiconductor circuit 7 on the silicon substrate 6, the space of the silicon substrate 6 can be effectively used. Further, since the semiconductor circuit 7 can be integrally formed at the silicon substrate 6, a size of the oscillator 1 can be reduced. In particular, as compared with when the semiconductor circuit 7 is formed at the upper surface 6a side, by forming the semiconductor circuit 7 on the lower surface 6b side of the silicon substrate 6, a region in which the semiconductor circuit 7 can be formed is widened since there is no bonding region with the lid 4. Therefore, the degree of design freedom of the semiconductor circuit 7 is increased. The semiconductor circuit 7 may be formed at the upper surface 6a side of the silicon substrate 6.

The terminal layer 75 includes a plurality of external terminals 50 for coupling the semiconductor circuit 7 to an external apparatus including the inspection apparatus 200.

The through-hole 61 is provided with a wiring 8. The wiring 8 is electrically coupled to an electrode pad 72p of the wiring layer 72 on the lower surface 6b side of the silicon substrate 6, and is electrically coupled to a bonding member B on the upper surface 6a side of the silicon substrate 6. The bonding member B is electrically coupled to an excitation electrode of the vibration element 3.

The wiring 8 includes a first wiring 81 and a second wiring 82. The through-hole 61 is filled with the first wiring 81, and the first wiring 81 is disposed to bury a bottom portion of the through-hole 61. The second wiring 82 is electrically coupled to the first wiring 81 by overlapping the first wiring 81 from an upper side.

An organic resin film 63 is provided between an inner peripheral surface of the through-hole 61 and the first wiring 81. The organic resin film 63 has an insulating property, and insulates the first wiring 81 and the silicon substrate 6.

An organic resin film 64 is provided between the second wiring 82 overlapping the bonding member B and the upper surface 6a of the silicon substrate 6 in a plan view. The organic resin film 64 functions as a stress relaxation layer that alleviates stress generated when the vibration element 3 is pressed and crimped to the bonding member B.

### 1.2.2. Configuration of Lid 4

The lid 4 has a bottomed recess portion 41 that is open on a lower surface of the lid 4, and accommodates the vibration element 3 therein. The lid 4 is bonded to an upper surface of the mother substrate 5, that is, the upper surface 6a of the silicon substrate 6 via a bonding member 11 on the lower surface of the lid 4. The bonding member 11 is made of, for example, gold. The bonding member 11 made of gold is provided on each joining surface of the lid 4 and the mother substrate 5, and the bonding members 11 are bonded to each other by active bonding. Therefore, the accommodation space S for accommodating the vibration element 3 is formed between the lid 4 and the mother substrate 5.

The accommodation space S is airtight, and is in a decompressed state, preferably in a state closer to a vacuum. Therefore, a viscous resistance is reduced, and an oscillation characteristic of the vibration element 3 is improved. Meanwhile, an atmosphere of the accommodation space S is not particularly limited.

The lid 4 is obtained by individualizing the Lid substrate 4w made of a silicon wafer. In this manner, the lid 4 and the silicon substrate 6 are made of silicon. Therefore, linear expansion coefficients of the lid 4 and the silicon substrate 6 are equal to each other, occurrence of thermal stress due to thermal expansion is suppressed, and the oscillator 1 having excellent vibration characteristics is obtained. In addition, since the oscillator 1 can be formed by a semiconductor process, the oscillator 1 can be manufactured with high accuracy and can be miniaturized. The lid 4 may be formed of a wafer configured with a semiconductor material other than silicon such as Ge, GaP, GaAs, InP, or the like, for example.

### 1.2.3. Regarding Vibration Element 3

The vibration element 3 is a crystal resonator. The vibration element 3 may be a surface acoustic wave (SAW) resonator, another piezoelectric resonator, a micro electro mechanical systems (MEMS) resonator, or the like.

As the substrate material of the vibration element 3, a piezoelectric single crystal such as quartz, lithium tantalate, and lithium niobate, a piezoelectric material such as a piezoelectric ceramic such as lead zirconate titanate, or a silicon semiconductor material can be used. As an excitation unit of the vibration element 3, an excitation unit using a piezoelectric effect may be used, or an electrostatic drive using a Coulomb force may be used.

### 1.2.4. Functional Configuration of Oscillator 1

As illustrated in FIG. 4, in the present embodiment, the control circuit 2 is configured with an oscillation control circuit 10, the storage section 20, a measurement section 30, the correction circuit 40, a digital control circuit 91, a temperature sensor 92, a regulator circuit 93, a serial interface (I/F) circuit 94, and an output circuit 95. The control circuit 2 is electrically coupled to the external terminal 50 (see FIG. 3) and is electrically coupled to the vibration element 3 via the wiring 8 and the bonding member B.

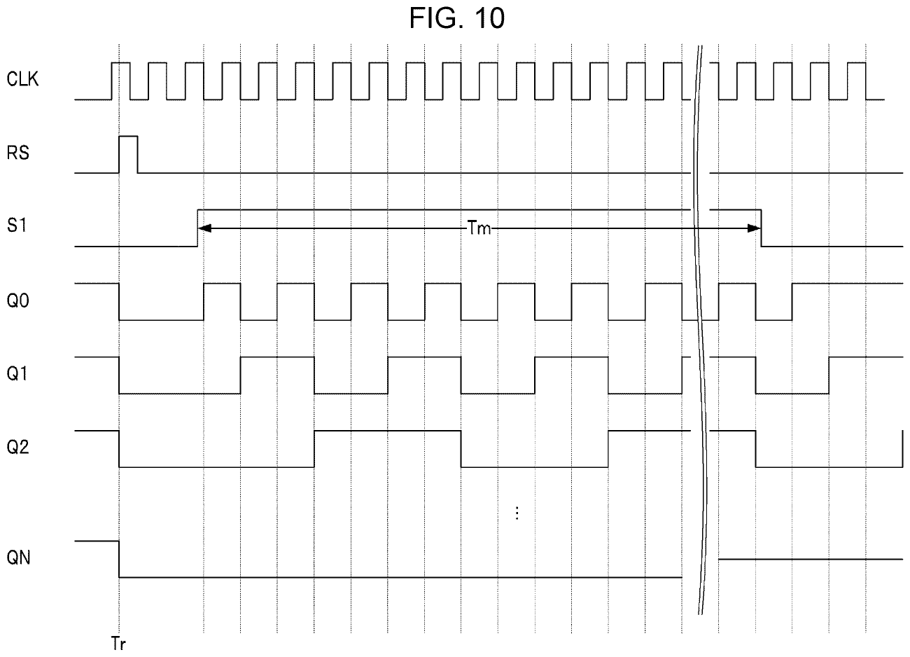

The external terminal 50 includes a power supply terminal VDD, a ground terminal GND, a terminal TS1 to which a first signal S1 for determining a measurement period Tm of a frequency (see FIG. 10) is input, a terminal SCL and a terminal SDA for serial communication, and an output terminal OUT. In FIG. 4, the terminal TS1 and the output terminal OUT are provided as terminals different from the terminals SCL and SDA, but these terminals may be common terminals. The wiring 8 includes an XO terminal and an XI terminal, and the bonding member B is a bump for mounting the vibration element 3.

The regulator circuit 93 generates a constant voltage that is a power supply voltage or a reference voltage of some or all of the oscillation control circuit 10, the measurement section 30, the correction circuit 40, the digital control circuit 91, the output circuit 95, and the like, based on a power supply voltage supplied from the VDD terminal.

The serial interface circuit 94 is a circuit that serves as an interface for communication between an external apparatus including the inspection apparatus 200 and the oscillator 1. The serial interface circuit 94 is a circuit that performs, for example, I2C communication.

The storage section 20 includes a non-volatile memory 21 and a register 22. The register 22 can store information transmitted by the external apparatus, via the terminal SDA and the serial interface circuit 94. In addition, the register 22 can output the information stored in the register 22 to the external apparatus, via the terminal SDA and the serial interface circuit 94.

The non-volatile memory 21 is a storage circuit for storing various types of control data, and may be, for example, various rewritable non-volatile memories such as an electrically erasable programmable read-only memory (EEPROM) and a flash memory, or various non-rewritable non-volatile memories such as a one-time programmable read only memory (One Time PROM).

The digital control circuit 91 can store the information stored in the register 22 in the non-volatile memory 21, and can store the information stored in the non-volatile memory 21 in the register 22.

The non-volatile memory 21 stores temperature compensation data (0th-order temperature compensation data, . . . , and nth-order temperature compensation data) for controlling the correction circuit 40 that corrects temperature characteristics of the vibration element 3. Since the 0th-order temperature compensation data is data that does not depend on a temperature, a frequency at a reference temperature is adjusted by the 0th-order temperature compensation data. n is a positive integer value. Further, the non-volatile memory 21 may store data for controlling the output circuit 95 and the like. In the present embodiment, the temperature compensation data is an example of correction information.

The temperature compensation data is data for correcting frequency temperature characteristics of the oscillator 1, which is calculated in an adjustment step S6 for the oscillator 1, which will be described below. The temperature compensation data is, for example, a value for outputting a voltage corresponding to each nth-order component of the 0th-order to nth-order frequency temperature characteristics of an oscillation signal CLK in the correction circuit 40. For example, when the vibration element 3 is an AT-cut crystal oscillator, the frequency temperature characteristic has a cubic curve, and thus an integer value of 3 or more is selected as n. The temperature compensation data may include compensation data of all orders of 0th-order to nth-order, or may include only some pieces of the 0th-order to nth-order compensation data.

Various types of data including the temperature compensation data stored in the non-volatile memory 21 are transferred from the non-volatile memory 21 to the register 22 when the power is turned on in the control circuit 2 (when the voltage of the VDD terminal rises from 0 V to a desired voltage), and held in the register 22. The temperature compensation data (0th-order temperature compensation data, . . . , and nth-order temperature compensation data) held by the register 22 is input to the correction circuit 40.

The oscillation control circuit 10 is a circuit that controls oscillation of the vibration element 3. Specifically, the oscillation control circuit 10 amplifies an output signal of the vibration element 3 and feeds back the amplified signal to the vibration element 3 to cause the vibration element 3 to oscillate, and outputs the oscillation signal CLK based on the oscillation of the vibration element 3. In the present embodiment, the oscillation control circuit 10 includes a variable capacitance element for temperature adjustment, and a frequency of the oscillation signal CLK output from the oscillation control circuit 10 can be changed by changing a voltage applied to the variable capacitance element.

An output voltage of the correction circuit 40 is configured to be applied to the variable capacitance element, and the voltage that offsets the change in the frequency of the oscillation signal CLK due to the temperature is applied to the variable capacitance element, so that the frequency is compensated for the temperature such that the frequency does not change for a predetermined range of temperature change.

The temperature sensor 92 is a temperature-sensitive element that outputs a signal (for example, a voltage according to the temperature) according to the temperature in the periphery thereof. The temperature sensor 92 may have a positive polarity in which the output voltage is higher as the temperature is higher, or may have a negative polarity in which the output voltage is lower as the temperature is higher. As the temperature sensor 92, it is desirable that the output voltage changes as linearly as possible with respect to the temperature change in a desired temperature range in which the operation of the oscillator 1 is guaranteed. In the present embodiment, the output voltage corresponding to the temperature detected by the temperature sensor 92 is input to the digital control circuit 91 via an analog-digital conversion circuit (not illustrated).

The measurement section 30 is a circuit that measures information corresponding to the frequency of the oscillation signal CLK output from the oscillation control circuit 10. In the present embodiment, the measurement section 30 is configured with a counter. In the present embodiment, the information corresponding to the frequency of the oscillation signal CLK is a pulse count Np of the oscillation signal CLK.

The measurement section 30 is a counter that counts the number of pulses of the oscillation signal CLK, and can be realized by, for example, a known circuit or the like in which a frequency divider circuit is serially coupled. The number of couplings of the frequency divider circuit may be a number required to represent the number of bits indicating the count value.

The oscillation signal CLK and the first signal S1 which is input from the terminal TS1 are input to the measurement section 30. In the present embodiment, the first signal S1 is a signal having a pulse width indicating a length of the measurement period Tm. The pulse width of the first signal S1, that is, the measurement period Tm is accurately determined by an internal clock having a known frequency in the inspection apparatus 200. Therefore, in the present embodiment, a frequency of the oscillator 1 can be accurately specified by the pulse count Np/measurement period Tm.

When the first signal S1 for determining the measurement period Tm of the oscillation signal CLK is input from the outside via the terminal TS1, the measurement section 30 counts the pulse count Np of the oscillation signal CLK output in the measurement period Tm. In the present embodiment, the first signal S1 is an example of a signal supplied to the control circuit 2 via the external terminal 50.

That is, the measurement section 30 includes a circuit in which the oscillation signal CLK is input to the frequency divider circuit in a period (a period of a high level) in which the first signal S1 is input to the measurement section 30, and the oscillation signal CLK is not input to the frequency divider circuit in a period in which the first signal S1 is not input to the measurement section 30. Such a circuit can be realized by various known configurations. In addition, each frequency divider circuit included in the measurement section 30 is configured to reset the count value to 0 by a reset signal RS. The output of each frequency divider circuit becomes a bit value indicating the count value.

When the frequency of the oscillation signal CLK of the oscillator 1 is measured, the pulse count, which is information corresponding to the frequency, is written in the register 22. The data written in the register 22 is written in the non-volatile memory 21. In addition, when the register 22 is read from the inspection apparatus 200, the pulse count is output from the register 22 to the inspection apparatus 200 via the terminal SDA and the serial interface circuit 94.

The digital control circuit 91 is a processor that performs various digital processes. The various digital processes include a control process on the correction circuit 40 and a process for measuring the frequency of the oscillation signal CLK.

In the control process on the correction circuit 40, the digital control circuit 91 outputs a control signal for instructing a 0th-order temperature compensation voltage to an nth-order temperature compensation voltage, based on the 0th-order temperature compensation data to the nth-order temperature compensation data stored in the register 22.

The correction circuit 40 generates a voltage (temperature compensation voltage) for compensating the frequency temperature characteristics of the vibration element 3 based on the control signal from the digital control circuit 91, and applies the voltage to one end of a variable capacitance element (not illustrated) that functions as a load capacitance of the oscillation control circuit 10.

Therefore, the oscillation frequency of the oscillation control circuit 10 is controlled to be substantially constant regardless of the temperature. In the present embodiment, the correction circuit 40 is configured with a 0th-order voltage generation circuit 40-0 to an nth-order voltage generation circuit 40-n and an addition circuit 42.

The 0th-order voltage generation circuit 40-0 to the nth-order voltage generation circuit 40-n respectively generate a 0th-order temperature compensation voltage to an nth-order temperature compensation voltage for compensating for the 0th-order component to the nth-order component of the frequency temperature characteristics of the vibration element 3 according to the control signal from the digital control circuit 91.

The addition circuit 42 adds the 0th-order temperature compensation voltage to the nth-order temperature compensation voltage respectively output by the 0th-order voltage generation circuit 40-0 to the nth-order voltage generation circuit 40-n, and outputs the resultant voltage. The output voltage of the addition circuit 42 is an output voltage (temperature compensation voltage) of the correction circuit 40.

The oscillation signal CLK output by the oscillation control circuit 10 is input to the output circuit 95, and the output circuit 95 generates the oscillation signal CLK for external output and outputs the oscillation signal CLK for external output to the outside via the OUT terminal. For example, a division ratio and an output level of the oscillation signal CLK in the output circuit 95 may be controlled by the control data held in the register 22.

The oscillator 1 configured as described above functions as a voltage controlled temperature compensated crystal oscillator (VC-TCXO) that outputs the oscillation signal CLK having a constant frequency in a desired temperature range, regardless of the temperature (when the vibration element 3 is a crystal oscillator).

### 1.3. Manufacturing Method of Oscillator 1

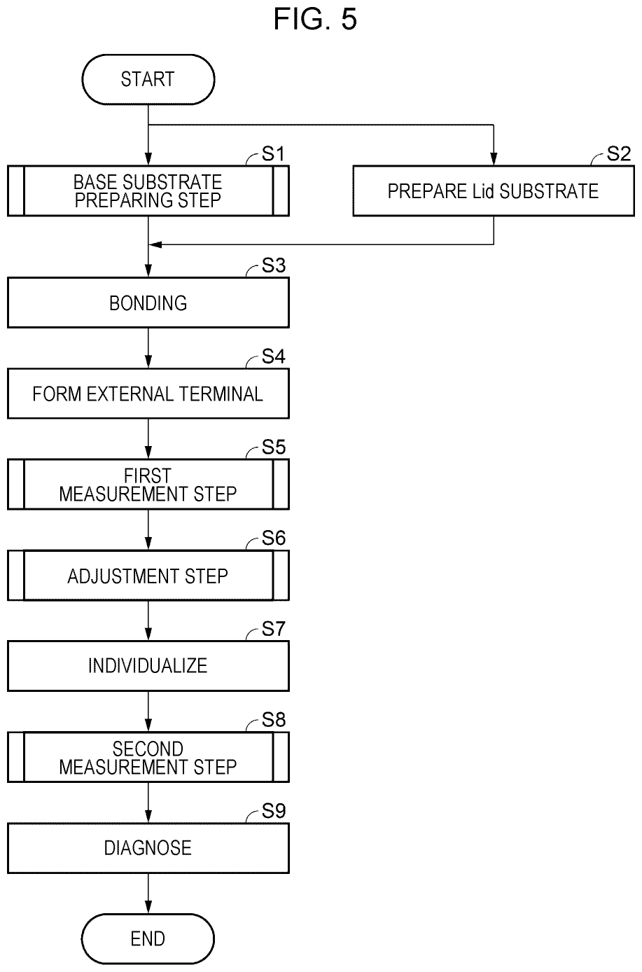

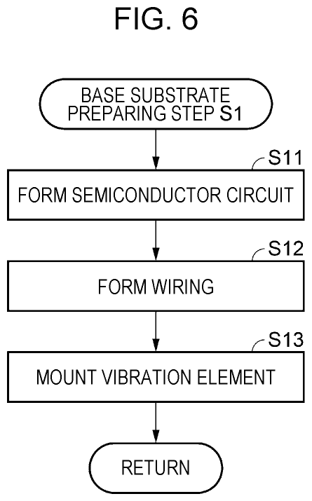

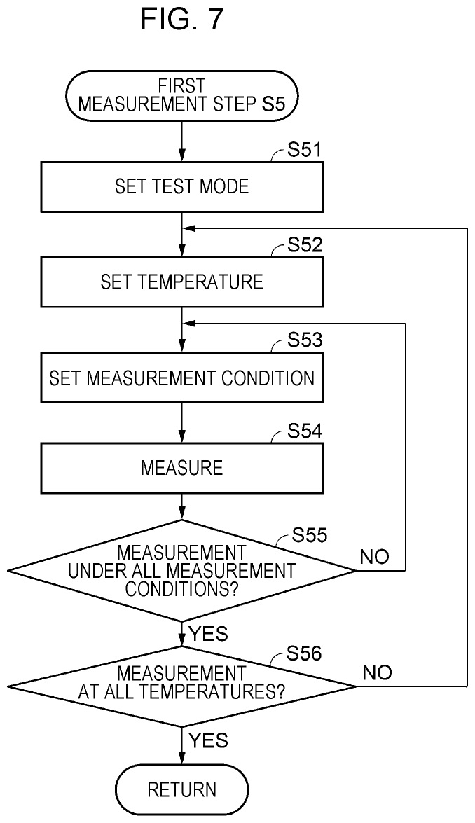

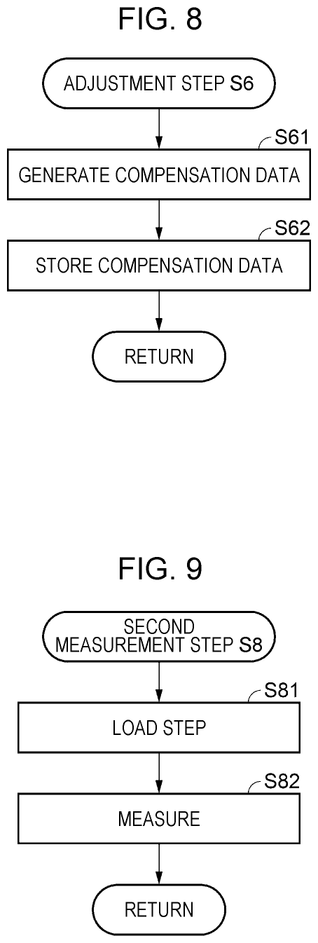

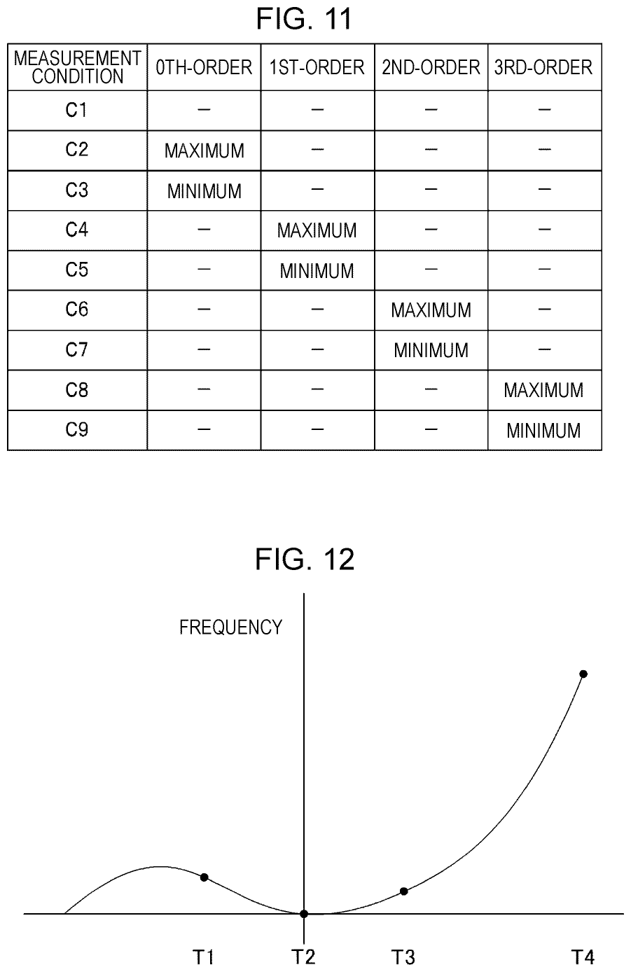

Next, a manufacturing method of the oscillator 1 will be described with reference to the drawings. FIG. 5 is a flowchart illustrating a manufacturing method of the oscillator 1. FIG. 6 is a flowchart illustrating details of a base substrate preparing step S1. FIG. 7 is a flowchart illustrating details of a first measurement step S5. FIG. 8 is a flowchart illustrating details of an adjustment step S6. FIG. 9 is a flowchart illustrating details of a second measurement step S8. FIG. 10 is a timing chart illustrating examples of an input signal and an output signal of the measurement section 30. FIG. 11 is a diagram illustrating an example of a measurement condition Cy. FIG. 12 is a diagram illustrating a temperature characteristic of a frequency of the oscillator 1.

As illustrated in FIG. 5, the manufacturing method of the oscillator 1 includes the step S1 of preparing the base substrate 5w, a step S2 of preparing the Lid substrate 4w, a step S3 of bonding the base substrate 5w and the Lid substrate 4w to form the wafer substrate 100, a step S4 of forming the external terminal 50, the first measurement step S5 of measuring each oscillator 1 in a state of the wafer substrate 100, the step S6 of adjusting a frequency of each oscillator 1, a step S7 of individualizing the wafer substrate 100, the second measurement step S8 of measuring the frequency of the individualized oscillator 1, and a step S9 of diagnosing the presence or absence of a fault of the oscillator 1.

In the present embodiment, the step S1, the step S2, the step S3, the step S4, and the step S7 are executed by using the manufacturing apparatus 300, and the step S5, the step S6, the step S8, and the step S9 are executed by using the inspection apparatus 200.

### Base Substrate Preparing Step

As illustrated in FIG. 6, the base substrate preparing step S1 includes a step S11 of forming the semiconductor circuit 7 on the silicon substrate 6 made of a silicon wafer, a step S12 of forming the wiring 8 or the like, and a step S13 of mounting the vibration element 3 on the base substrate 5w.

In the step S11, the semiconductor circuit 7 including the control circuit 2 is formed at the lower surface 6b side of the silicon substrate 6, that is, on a lower surface side of the base substrate 5w.

In the step S12, the through-hole 61 (see FIG. 3) exposing the electrode pad 72p is formed from the upper surface 6a side of the silicon substrate 6, that is, from an upper surface side of the base substrate 5w, the through-hole 61 is filled with the first wiring 81, and a through-electrode is formed in the through-hole 61. In addition, the second wiring 82 is formed at the upper surface side of the base substrate 5w to form the wiring 8 electrically coupled to the semiconductor circuit 7. The bonding member B as a bump is formed at an upper surface of the wiring 8.

In the step S13, the vibration element 3 is mounted on the bonding member B, and the vibration element 3 is electrically coupled to the semiconductor circuit 7.

With reference to FIG. 5, in the step S2, a plurality of recess portions 41 are formed at the Lid substrate 4w. In the step S3, the base substrate 5w and the Lid substrate 4w are bonded to form the wafer substrate 100. In the present embodiment, the base substrate 5w and the Lid substrate 4w are bonded to each other in a vacuum atmosphere. That is, the accommodation space S in which the vibration element 3 is accommodated is in a decompressed state.

The plurality of oscillators 1 are formed at the wafer substrate 100. In the present embodiment, a size of the oscillator 1 in a plan view is 1 mm×0.8 mm, and tens of thousands of oscillators 1 are formed at one surface of the wafer substrate 100.

In the step S4, the external terminal 50 is formed at a lower surface of the wafer substrate 100. The external terminal 50 has a larger area than the electrode pad 71p in a plan view. Plating is performed on a lower surface of the external terminal 50. The plating is Ni/Pb/Au plating, Ni/Au plating, or SnD/Ag plating. In addition, solder printing may be performed instead of plating. In addition, a solder ball may be mounted instead of the plating. The step S4 may be executed between the step S11 and the step S12.

In the first measurement step S5 to be described below, the number of measurements is large, and thus the number of times the probe 230 touches down on the external terminal 50 is also large. Therefore, by performing surface treatment on the external terminal 50 by plating or the like, even when the number of times of touch-down of the probe 230 is increased, the damage to the external terminal 50 can be suppressed.

### First Measurement Step

In the first measurement step S5 illustrated in FIG. 7, a temperature characteristic of the frequency of the oscillator 1 is measured. The first measurement step S5 includes steps S51 to S56. In the first measurement step S5, the oscillator 1 of the wafer substrate 100 is electrically coupled to the inspection apparatus 200. When the probe 230 of the inspection apparatus 200 touches down the external terminal 50 of the oscillator 1, measurement by the inspection apparatus 200 can be performed. The inspection apparatus 200 is devised to measure the plurality of oscillators 1 in one measurement.

In the step S51, the oscillator 1 is set to a test mode. The oscillator 1 has a normal mode and the test mode. The normal mode is a mode in which the oscillation signal CLK or a signal generated based on the oscillation signal CLK is output from the OUT terminal of the oscillator 1, and the test mode is a mode for performing frequency measurement or the like.

In the step S52, a temperature of the oscillator 1 formed at the wafer substrate 100 is adjusted to a predetermined measurement temperature. In the present embodiment, the temperature characteristics of the frequency of the oscillator 1 are measured at a plurality of temperatures. The measurement temperature is, for example, 0° C., 25° C., 50° C., and 95° C. When the oscillator 1 is a simple package crystal oscillator (SPXO), the measurement temperature may be measured at only one temperature. The SPXO refers to an oscillator that draws out a frequency stability of the crystal as it is without temperature compensation and temperature control.

In the step S53, a measurement condition is set. FIG. 11 illustrates an example of the measurement condition. When the correction circuit 40 (see FIG. 4) includes the 0th-order voltage generation circuit 40-0 to the 3rd-order voltage generation circuit 40-3, the 0th-order to the 3rd-order illustrated in FIG. 11 indicate the presence or absence of correction and a magnitude of the correction in the 0th-order voltage generation circuit 40-0 to the 3rd-order voltage generation circuit 40-3.

For example, no correction is performed on an order indicated by “-” in FIG. 11. Therefore, for a measurement condition C1, no correction is performed for any of the 0th-order voltage generation circuit 40-0 to the 3rd-order voltage generation circuit 40-3. That is, the pulse count Np of the oscillation signal CLK output in the measurement period Tm is not corrected.

FIG. 11 illustrates that for an order indicated as “maximum”, the correction is performed with the maximum value of the voltage that can be output by a voltage generation circuit of the order. For example, for a measurement condition C2, the maximum value of the voltage that can be output in the 0th-order voltage generation circuit 40-0 is output, and no correction is performed for the 1st-order voltage generation circuit 40-1 to the 3rd-order voltage generation circuit 40-3.

FIG. 11 illustrates that for an order indicated as “minimum”, the correction is performed with the minimum value of the voltage that can be output by a voltage generation circuit of the order. For example, for a measurement condition C5, the minimum value of the voltage that can be output in the 1st-order voltage generation circuit 40-1 is output, and no correction is performed for the 0th-order voltage generation circuit 40-0, the 2nd-order voltage generation circuit 40-2, and the 3rd-order voltage generation circuit 40-3.

As described above, in the present embodiment, the condition in which no correction is performed for all of the 0th-order voltage generation circuit 40-0 to the 3rd-order voltage generation circuit 40-3, the condition in which the correction is performed for only any one with the maximum value of the voltage, and the condition in which the correction is performed for only any one with the minimum value of the voltage are defined, and a total of nine measurement conditions, that is, the measurement condition C1 to a measurement condition C9 are defined.

With reference to FIG. 7, in the step S54, the frequency of the oscillator 1 is measured. In the present embodiment, the measurement section 30 measures the pulse count Np of the oscillation signal CLK. As illustrated in FIG. 10, the oscillation signal CLK is input to the measurement section 30. The oscillation signal CLK is a pulse signal in which a high level and a low level are repeated at regular intervals. In the present embodiment, the measurement section 30 counts the number of times the pulse signal becomes a high level within the measurement period Tm indicated by the first signal S1, as the pulse count Np.

When starting the counting, the reset signal RS is input from the digital control circuit 91 to the measurement section 30, and the measurement section 30 is reset by the reset signal RS. Thereafter, when the first signal S1 is input to the measurement section 30, the counting by each frequency divider circuit of the measurement section 30 is started.

In FIG. 10, an output of each frequency divider circuit is indicated as Q0 to QN. A numerical value added to Q is a natural number, and corresponds to a bit of a count value. That is, in the example illustrated in FIG. 10, the count value is represented by a value of (N+1) digits from the value Q0 of the first bit to the value QN of the (N+1)th bit. The value of N is not limited, but is a value of a sufficient number for counting the pulse count Np within the measurement period Tm.

When the pulse count Np is counted over a period in which the first signal S1 is at a high level, and the first signal S1 changes to a low level after the measurement period Tm elapses, the digital control circuit 91 acquires the pulse count Np from the measurement section 30 and stores the pulse count Np in the register 22. When the pulse count Np is stored in the register 22, the pulse count Np is stored in the non-volatile memory 21. According to this configuration, even when the power of the oscillator 1 is turned off, the measured pulse count Np is held in the storage section 20, and the pulse count Np can be read when the power is turned on again.

The above process is executed for each of the plurality of oscillators 1 formed at the wafer substrate 100. That is, the pulse count Np, which is a measurement result under the same temperature and the same measurement condition, is acquired in each oscillator 1, and stored in the register 22 and the non-volatile memory 21 of each oscillator 1.

In a step S55, the inspection apparatus 200 determines whether or not the measurement is performed under all the measurement conditions. In the step S55, when it is determined that the measurement is not completed under all the measurement conditions, the process proceeds to the step S53, and the process after the step S53 is repeated. When it is determined that the measurement is completed under all the measurement conditions, the process proceeds to the step S56.

According to the above configuration, the pulse count Np corresponding to the frequency of the oscillation signal CLK is measured under each measurement condition. That is, the measurement section 30 measures the pulse count Np for each of the measurement condition C1 to the measurement condition C9 at a predetermined measurement temperature. The digital control circuit 91 stores the measurement result in a predetermined address of the register 22 and the non-volatile memory 21. In the present embodiment, an address at which the measurement result for each temperature and measurement condition is stored is determined in advance, and the inspection apparatus 200 can acquire the measurement result for any temperature and measurement condition by designating the address to be read.

In the step S56, the inspection apparatus 200 determines whether or not the measurement is performed at all of the predetermined measurement temperatures. In the step S56, when it is determined that the measurement is not completed at all the predetermined measurement temperatures, the process proceeds to step S52 and the process after step S52 is repeated. When it is determined that the measurement is completed at all the predetermined measurement temperatures, the process exit the first measurement step S5 and proceeds to the adjustment step S6.

### Adjustment Step

As illustrated in FIG. 8, the adjustment step S6 includes a step S61 of generating compensation data and a step S62 of storing the compensation data. In the adjustment step S6, the frequency of each oscillator 1 is adjusted to a predetermined reference frequency. In the present embodiment, the predetermined frequency which is a reference is an example of a first frequency.

In the step S61, the inspection apparatus 200 first acquires the pulse count Np for each temperature and each measurement condition. Since the pulse count Np for each temperature and measurement condition is stored at a predetermined address of the register 22 of the oscillator 1, the inspection apparatus 200 designates the address to read the pulse count Np.

The digital control circuit 91 of the oscillator 1 acquires the pulse count Np stored at the address set as the reading target, and outputs the pulse count Np to the inspection apparatus 200 via the serial interface circuit 94. The read pulse count Np is stored in a storage medium (not illustrated) of the inspection apparatus 200 in association with the temperature and the measurement condition. The inspection apparatus 200 acquires the pulse count Np in all the temperatures and measurement conditions for all the plurality of oscillators 1.

Next, the inspection apparatus 200 converts the pulse count Np into a frequency. Specifically, the inspection apparatus 200 acquires the frequency by dividing the pulse count Np by the measurement period Tm. Here, the inspection apparatus 200 acquires the frequencies in all the temperatures and measurement conditions for all the plurality of oscillators 1.

Next, the inspection apparatus 200 acquires a 0th-order coefficient to a 3rd-order coefficient. Specifically, in the present example, it is considered that a relationship between the frequency of the oscillation signal CLK and the temperature is represented by a cubic equation. Therefore, in the inspection apparatus 200, it is considered to represent a frequency F as a function of a temperature T as in Equation (1).

$$F = {aT}^{3} + {bT}^{2} + cT + d \qquad ( 1 )$$

In addition, a, b, c, and d are a 3rd-order coefficient, a 2nd-order coefficient, a 1st-order coefficient, and a 0th-order coefficient, respectively.

The inspection apparatus 200 acquires a cubic equation that approximates the relationship between the frequency and the temperature based on the frequency acquired from the pulse count Np and the temperature, which are measured under each measurement condition. FIG. 12 is a graph in which frequencies of temperatures T1 to T4 under the measurement condition C1 are plotted. In the graph illustrated in FIG. 12, a horizontal axis is the temperature, and a vertical axis is the frequency. The measurement condition C1 is a temperature characteristic of the frequency of the oscillation signal CLK in a state in which no correction by the correction circuit 40 is performed. Therefore, by using the frequencies for the four temperatures measured under the measurement condition C1, a cubic equation can be specified by using a known approximation, and the cubic equation can be regarded as the temperature characteristic of the frequency of the oscillation signal CLK.

When each coefficient of the cubic equation obtained by the approximation is represented as a1, b1, c1, and d1, the cubic equation of the frequency F is represented as in Equation (2).

$$F = a 1 {T}^{3} + b 1 {T}^{2} + c 1 T + d 1 \qquad ( 2 )$$

A solid line illustrated in FIG. 12 illustrates the result of plotting Equation (2) on the graph.

In the measurement condition C1, since the frequency of the oscillation signal CLK has a temperature characteristic as in Equation (2), when the correction circuit 40 can give the oscillation control circuit 10 an inverse characteristic of the characteristic, that is, a characteristic as in Equation (3), the temperature characteristic of Equation (2) can be canceled.

$$F = - a 1 {T}^{3} - b 1 {T}^{2} - c 1 T - d 1 \qquad ( 3 )$$

The inspection apparatus 200 determines a correction coefficient for performing the cancellation described above. That is, in the inspection apparatus 200, it is assumed that −d1 of Equation (3) specified based on the measurement result of the measurement condition C1 is a 0th-order coefficient, −c1 is a 1st-order coefficient, −b1 is a 2nd-order coefficient, and −a1 is a 3rd-order coefficient. The inspection apparatus 200 acquires the 0th-order coefficient to the 3rd-order coefficient for all of the plurality of oscillators 1.

Next, the inspection apparatus 200 generates 0th-order temperature compensation data to 3rd-order temperature compensation data. Specifically, the inspection apparatus 200 specifies a temperature compensation voltage for realizing each of the 0th-order coefficient to the 3rd-order coefficient, and specifies temperature compensation data for outputting the temperature compensation voltage.

Therefore, the inspection apparatus 200 specifies the temperature compensation voltages for realizing each of the 0th-order coefficient to the 3rd-order coefficient by using the measurement results of the measurement condition C2 to the measurement condition C9. Specifically, the inspection apparatus 200 specifies a 0th-order temperature compensation voltage by using the measurement conditions C2 and C3. The measurement result under the measurement condition C2 is a measurement result in a state in which the maximum value of a voltage that can be output in the 0th-order voltage generation circuit 40-0 is output and no correction is performed for the 1st-order voltage generation circuit 40-1 to the 3rd-order voltage generation circuit 40-3. The measurement result under the measurement condition C3 is a measurement result in a state in which the minimum value of the voltage that can be output in the 0th-order voltage generation circuit 40-0 is output, and no correction is performed for the 1st-order voltage generation circuit 40-1 to the 3rd-order voltage generation circuit 40-3.

Therefore, when the same approximation as in Equation (3) is performed based on the frequency obtained from the pulse count, which is the measurement result of the measurement condition C2, a correction coefficient dmax in a state in which the maximum value of the voltage that can be output in the 0th-order voltage generation circuit 40-0 is output can be acquired. In addition, when the same approximation as in Equation (3) is performed based on the frequency obtained from the pulse count, which is the measurement result of the measurement condition C3, a correction coefficient dmin in a state in which the minimum value of the voltage that can be output in the 0th-order voltage generation circuit 40-0 is output can be acquired.

According to the correction coefficients dmax and dmin, a range of the correction coefficients changed by the 0th-order voltage generation circuit 40-0 can be specified. That is, it can be said that the range of the correction coefficient changed by the 0th-order voltage generation circuit 40-0 is a range of dmin to dmax.

The 0th-order temperature compensation data is a numerical value within a predetermined range, and when the 0th-order temperature compensation data is changed in a range from the maximum value to the minimum value, the correction coefficient can be changed in a range of dmax to dmin.

In addition, it can be considered that the change in the correction coefficient with respect to the change in the 0th-order temperature compensation data is linear. Therefore, when the 0th-order coefficient “−d1” described above and the range dmin to dmax of the correction coefficient are compared, the 0th-order temperature compensation data necessary for outputting the 0th-order temperature compensation voltage corresponding to the 0th-order coefficient “−d1” can be specified.

The inspection apparatus 200 executes the same process as the above process for the 1st-order coefficient to the 3rd-order coefficient. That is, the inspection apparatus 200 specifies the 1st-order temperature compensation data by using the measurement conditions C4 and C5, specifies the 2nd-order temperature compensation data by using the measurement conditions C6 and C7, and specifies the 3rd-order temperature compensation data by using the measurement conditions C8 and C9.

In the step S62, the inspection apparatus 200 writes the 0th-order temperature compensation data to the 3rd-order temperature compensation data at a predetermined address of the oscillator 1. That is, the inspection apparatus 200 outputs a command for storing each temperature compensation data at the predetermined address to the oscillator 1.

The digital control circuit 91 acquires the command via the SDA terminal and the serial interface circuit 94, and stores each temperature compensation data in the address indicated by the command. The inspection apparatus 200 executes the step S61 and the step S62 for all of the plurality of oscillators 1 formed at the wafer substrate 100. By the above steps, the frequency of each oscillator 1 is adjusted to a predetermined frequency that is a reference.

With reference to FIG. 5, in the step S7, the wafer substrate 100 is individualized for each oscillator 1. The wafer substrate 100 is individualized for each oscillator 1, by using a scribing device to cut the wafer substrate 100 along the division line DL (see FIG. 2A and the like).

### Second Measurement Step

In the second measurement step S8, a frequency of the individualized oscillator 1 is measured. In the following description, the frequency of the individualized oscillator 1 measured in the second measurement step S8 is referred to as a second frequency. As illustrated in FIG. 9, the second measurement step S8 includes a step S81 of applying a load to the oscillator 1 and a step S82 of measuring the frequency of the oscillator 1.

In the step S81, a load test is executed on the oscillator 1. As the load test, for example, a pressure cooker test (PCT), a high accelerated stress test (HAST), a high temperature storage test (HTS), or the like is executed. By performing the load test, a bonding defect, that is, an airtightness defect of the accommodation space S of the oscillator 1 can be efficiently specified. The load step S81 may be omitted.

In the step S82, the frequency (second frequency) of the individualized oscillator 1 is measured. The step S82 is executed in the same manner as the step S54 described above. The step S82 may be executed at one measurement temperature, for example, at a room temperature. In the step S82, in order to improve the efficiency of the measurement, the plurality of oscillators 1 are arranged on the tray 260 (see FIG. 1) and the measurement is performed.

With reference to FIG. 5, in the step S9, it is diagnosed whether or not the individualized oscillator 1 has a fault. First, the inspection apparatus 200 reads the pulse count Np from the register 22 of the oscillator 1, and converts the pulse count Np into a frequency. The converted frequency is the frequency (second frequency) of the oscillator 1 measured in the step S82.

Next, the presence or absence of a fault is diagnosed by comparing the converted frequency (second frequency) with the predetermined frequency (first frequency) that is the reference described above, and determining a magnitude of a difference between the first frequency and the second frequency. In the present embodiment, the difference between the frequency (second frequency) of the oscillator 1 measured in the step S82 and the first frequency, that is, a predetermined value is several ppm of the first frequency.

When the difference between the frequency (second frequency) of the oscillator 1 measured in the step S82 and the first frequency is greater than the several ppm of the first frequency, the inspection apparatus 200 diagnoses the oscillator 1 to have a fault, and when the difference between the frequency (second frequency) of the oscillator 1 measured in the step S82 and the first frequency is equal to or less than the several ppm of the first frequency, the inspection apparatus 200 diagnoses the oscillator 1 as a non-defective product.

When the oscillator 1 is individualized from the wafer substrate 100, when an airtightness defect of the accommodation space S of the oscillator 1 occurs, the frequency (second frequency) of the oscillator 1 measured in the step S82 shifts by approximately several ppm of the first frequency. Therefore, by setting the predetermined value to the several ppm of the first frequency, the oscillator 1 in which the airtightness defect due to the individuation occurs can be accurately found.

As described above, the manufacturing method of the oscillator 1 of the present embodiment has the following effects. The manufacturing method of the oscillator 1 of the present embodiment includes: the step S1 to the step S4 as steps for preparing the wafer substrate 100 as a structure including the control circuit 2 having the storage section 20 and the correction circuit 40, the mother substrate 5 in which the external terminal 50 as a terminal coupled to the control circuit 2 is disposed, the vibration element 3 that is disposed corresponding to the control circuit 2 and constitutes the oscillator 1 together with the control circuit 2, and the lid 4 for accommodating the vibration element 3 together with the mother substrate 5; the first measurement step S5 of supplying the first signal S1 as a signal to the control circuit 2 via the external terminal 50 to measure a frequency of the oscillator 1; the adjustment step S6 as a step of storing temperature compensation data as correction information to be used in the correction circuit 40 in the storage section 20 in accordance with the measured frequency and adjusting the frequency of the oscillator 1 to a first frequency; the step S7 of individualizing the wafer substrate 100 for each oscillator 1 including the vibration element 3, the control circuit 2, and the external terminal 50; the step S82 of the second measurement step S8 of supplying the first signal S1 to the control circuit 2 via the external terminal 50 to measure the frequency of the oscillator 1; and the step S9 of performing a fault diagnosis on the oscillator 1 by comparing the frequency of the oscillator 1 (a second frequency) measured in the step S82 of the second measurement step S8 with the first frequency.

In this manner, in the manufacturing method of the oscillator 1 of the present embodiment, the frequency of the oscillator 1 is adjusted to the first frequency by measuring the frequency of the oscillator 1 by using the external terminal 50 in a state of the wafer substrate 100 and storing the correction information in the oscillator 1, and then the wafer substrate 100 is individualized, the frequency of the oscillator 1 (the second frequency) is measured again by using the external terminal 50 of the individualized oscillator 1, and the fault diagnosis is performed at the oscillator 1 based on the frequency of the oscillator 1 (the second frequency) measured in the step S82 of the second measurement step S8 and the first frequency. Therefore, even when an airtightness defect occurs in the oscillator 1 at the time of the individuation, the faulty oscillator 1 can be accurately detected.

In the step S9 of performing the fault diagnosis of the manufacturing method of the oscillator 1 of the present embodiment, when a difference between the frequency (second frequency) of the oscillator 1 measured in the step S82 of the second measurement step S8 and the first frequency is greater than several ppm of the first frequency as a predetermined value, a determination is made that the oscillator 1 is faulty, and when the difference is equal to or less than the several ppm of the first frequency, a determination is made that the oscillator 1 is normal. Therefore, even when an airtightness defect occurs in the oscillator 1 at the time of the individuation, the faulty oscillator 1 can be accurately detected.

In the manufacturing method of the oscillator 1 of the present embodiment, the control circuit 2 includes the measurement section 30 as a counter, and when the first signal S1 corresponding to the measurement period Tm of the frequency is supplied from the external terminal 50, the measurement section 30 performs counting based on the first signal S1, and the storage section 20 stores the result of the counting.

In this manner, the measurement period Tm is based on the first signal S1 supplied from the external terminal 50. Since the measurement section 30 performs the counting based on the first signal S1, the frequency of the oscillator 1 can be accurately specified depending on the result of the counting.

In the first measurement step S5 of the manufacturing method of the oscillator 1 of the present embodiment, the frequency of the oscillator 1 is measured at a plurality of temperatures, and in the adjustment step S6, the correction information is the temperature compensation data. Therefore, the manufacturing method of the oscillator 1 of the present embodiment can be an appropriate method for manufacturing a temperature compensated oscillator (TCXO).

In the manufacturing method of the oscillator 1 of the present embodiment, a model used in the correction circuit 40 is a polynomial, and the correction information is a correction coefficient used in the polynomial. Therefore, with the manufacturing method of the oscillator 1 of the present embodiment, the oscillator 1 with which accurate temperature compensation can be performed can be manufactured.

In the manufacturing method of the oscillator 1 of the present embodiment, after the step S7 of performing the individuation, the step S81 of applying a load to the oscillator 1 is provided before the second measurement step S82. In this manner, by executing the step S81 of applying THE load to the oscillator 1 before the second measurement step S82, the oscillator 1 in which a problem occurs in the bonding between the mother substrate 5 and the lid 4, that is, the oscillator 1 in which the accommodation space S is in an atmospheric state can be efficiently specified. Therefore, a market quality of the oscillator 1 manufactured by the manufacturing method of the oscillator 1 of the present embodiment can be improved. In other words, a defect occurrence rate after the sale of the oscillator 1 can be reduced.

In the manufacturing method of the oscillator 1 of the present embodiment, in the steps S1 to S4 as the steps of preparing the wafer substrate 100, the plating is performed on the external terminal 50 of the mother substrate 5.

In this manner, by plating the external terminal 50, even when the number of times of touching down of the probe 230 on the external terminal 50 is increased in the first measurement step S5 and the second measurement step S8, the damage to the external terminal 50 can be suppressed.

The preferred embodiments are described above, but the present disclosure is not limited to the embodiments described above. The configuration of each section of the present disclosure can be replaced with any configuration that has the same function as the embodiment described above, and any configuration can be added.

What is claimed is:

1. An oscillator manufacturing method comprising:
preparing a structure including a control circuit having a storage section and a correction circuit, a mother substrate on which a terminal coupled to the control circuit is disposed, a vibration element that is disposed corresponding to the control circuit and constitutes an oscillator together with the control circuit, and a lid that accommodates the vibration element together with the mother substrate;
a first measurement step of supplying a signal to the control circuit via the terminal to measure a frequency of the oscillator;
storing, in the storage section, correction information to be used in the correction circuit in accordance with the measured frequency, and adjusting the frequency of the oscillator to a first frequency;
individualizing the structure for each oscillator including the vibration element, the control circuit, and the terminal;
a second measurement step of supplying the signal to the control circuit via the terminal to measure the frequency of the oscillator; and
performing a fault diagnosis on the oscillator by comparing the frequency of the oscillator measured in the second measurement step with the first frequency.

2. The oscillator manufacturing method according to claim 1, wherein
in the performing of the fault diagnosis, when a difference between the frequency of the oscillator measured in the second measurement step and the first frequency is greater than a predetermined value, a determination is made that the oscillator is faulty, and when the difference is equal to or less than the predetermined value, a determination is made that the oscillator is normal.

3. The oscillator manufacturing method according to claim 1, wherein
the control circuit includes a counter, and when the signal corresponding to a measurement period of the frequency is supplied from the terminal, the counter performs counting based on the signal, and the storage section stores a result of the counting.

4. The oscillator manufacturing method according to claim 1, wherein
in the first measurement step, the frequency of the oscillator is measured at a plurality of temperatures, and
in the adjusting, the correction information is temperature compensation data.

5. The oscillator manufacturing method according to claim 1, wherein
a model used in the correction circuit is a polynomial, and
the correction information is a correction coefficient used in the polynomial.

6. The oscillator manufacturing method according to claim 1, further comprising:
applying a load to the oscillator after the step of individualizing and before the second measurement step.

7. The oscillator manufacturing method according to claim 1, wherein
in the preparing of the structure, plating is performed on the terminal of the mother substrate.
